(19) United States
(12) Patent Application Publication
(10) Pub. No.: US 2017/0351175 A1
(43) Pub. Date: Dec. 7, 2017

(54) SYNTHETIC PAPER

(71) Applicant: Mercene Labs AB, Stockholm (SE)

(72) Inventors: Jonas Hansson, Stockholm (SE); Hiroki Yasuga, Stockholm (SE); Wouter Van Der Wijngaart, Sollentuna (SE); Tommy Haraldsson, Järfäalla (SE)

(21) Appl. No.: 15/535,247

(22) PCT Filed: Jan. 18, 2016
(86) PCT No.: PCT/EP2016/050900

§ 371 Date: Jun. 12, 2017

(30) Foreign Application Priority Data
Jan. 16, 2015 (SE) 1500026-8
Oct. 22, 2015 (SE) 1500421-1

(51) Int. Cl. G03F 7/00; G03F 7/027; G03F 7/038; G03F 7/20

(52) U.S. Cl. CPC G03F 7/0037; G03F 7/2022; G03F 7/027; G03F 7/038; G03F 7/201

(57) ABSTRACT

A synthetic paper is manufactured with a method comprising the steps of: a) providing at least two types of pho to-polymerizable monomers, b) exposing the volume to a three-dimensional light pattern to induce a polymerization reaction, and c) removing uncured monomer to create an open microstructure. The volume comprises at least one monomer comprising at least two thiol groups and at least one monomer comprising at least two carbon-carbon double bonds, where the ratio (r₁) between the number of thiol groups and the number of carbon-carbon double bonds fulfils one of: 0.5≦r1≦0.9 and 1.1≦r1≦2. One advantage is that off stoichiometry creates an edge effect giving better defined boundaries between exposed and unexposed parts in the volume and giving a possibility to create thinner micro pillars. Another advantage is that it is easy to bind molecules to the surface to obtain desired surface properties.

### TECHNICAL FIELD

The present invention relates generally to a synthetic paper and a method for its manufacture.

### BACKGROUND

A porous lattice structure is know from U.S. Pat. No. 8,586,179. The porous lattice structure is operable for a fluid flow.

U.S. Pat. No. 7,653,279, U.S. Pat. No. 8,195,023, U.S. Pat. No. 8,315,499, U.S. Pat. No. 8,541,015, and U.S. Pat. No. 8,585,944 disclose ordered polymer microstructures that may be for instance slanting and/or interlocked. The microstructures are manufactured by exposure to actinic radiation through a mask, creating a desired pattern in a monomer reservoir. The monomers are cured by the light to the desired pattern.

Jacobsen et al in Adv. Mater. 2007, 19, 3892-3896 discloses an ordered microstructure. A thiol-ene polymer together with an UV free radical photo initiator is used.

The synthetic paper can replace cellulose based paper for applications where the paper creates a capillary flow.

For applications with a fluid flow it is a problem how to make the microstructures thinner and thereby having the possibility of creating higher capillary force.

### SUMMARY

It is an object of the present invention to obviate at least some of the disadvantages in the prior art and provide an improved method of manufacturing a micro structure.

The inventors have found that the use of off-stochiometry thiol-ene chemistry give an edge effect during the manufacturing process which allows for thinner micropillars and a sharper more well defined boundary.

In a first aspect there is provided a method for forming a three-dimensional ordered open microstructure with micro pillars, the method comprising the steps of:
a) providing a volume comprising at least two types of monomers with the ability to undergo a polymerization reaction upon exposure to actinic radiation,
b) exposing the volume comprising at least two types of monomers to at least one three-dimensional light pattern creating a pattern in the volume comprising at least two types of monomers, and wherein the exposure energy of the light pattern is sufficient to induce a polymerization reaction to create a cured polymer in a pattern, and
c) removing uncured monomer to leave behind the three-dimensional ordered open microstructure, corresponding to the pattern,
wherein the volume comprises at least one monomer comprising at least two thiol groups and at least one monomer comprising at least two carbon-carbon double bonds, with the proviso that the ratio (r₁) in the reaction mixture between the number of thiol groups and the number of carbon-carbon double bonds fulfils one of: 0.5≦r1≦0.9 and 1.1≦r1≦2.

In a second aspect there is provided a microstructure comprising micro pillars manufactured with the method described above.

In a third aspect there is provided the use of the microstructure manufactured according to the above method for at least one selected from the group consisting of a microfluidic component, a mechanical particle filter, a lateral flow assay device, a stretchable electronic device, artificial skin, self-assembling systems, a synthetic textile, and a writing paper.

Further aspects and embodiments are defined in the appended claims, which are specifically incorporated herein by reference.

One advantage is that thinner micro pillars can be manufactured which for instance offers the possibility to obtain high capillary force.

Another advantage is that the micro structure can be surface modified as desired. The off stoichiometry feature allows further groups to be bound to the surface when the reaction is completed.

For embodiments with interlocking micro pillars, the mechanical stability resulting from the pillar interlocking allows miniaturization and increased aspect ratio capillary pumps without pillar collapse as compared to freestanding vertical pillars that may collapse randomly.

The combination of pillar slanting and optical transparency allows observing several surface layers within the same line-of view.

### BRIEF DESCRIPTION OF THE DRAWINGS

The invention is now described, by way of example, with reference to the accompanying drawings, in which:

FIG. 1 shows a view of a microstructure,

FIG. 2 shows a view of two micro pillars indicating the tilting angle,

FIG. 3 shows different side views of microstructures with interlocking,

FIG. 4 shows top view of different arrangements of micro pillars on microstructures,

FIG. 5 shows side views of different microstructures,

FIG. 6 shows a schematic view of the manufacturing process with multidirectional UV-litography,

FIG. 7 shows different representations of a microstructures manufactured as described in the examples.

### DETAILED DESCRIPTION

Before the invention is disclosed and described in detail, it is to be understood that this invention is not limited to particular compounds, configurations, method steps, substrates, and materials disclosed herein as such compounds, configurations, method steps, substrates, and materials may vary somewhat. It is also to be understood that the terminology employed herein is used for the purpose of describing particular embodiments only and is not intended to be limiting since the scope of the present invention is limited only by the appended claims and equivalents thereof.

It must be noted that, as used in this specification and the appended claims, the singular forms “a”, “an” and “the” include plural referents unless the context clearly dictates otherwise.

If nothing else is defined, any terms and scientific terminology used herein are intended to have the meanings commonly understood by those of skill in the art to which this invention pertains.

The word “sheet” hereunder refers to a broad stretch or surface of at least one material. The lateral dimensions of such a sheet are from hundreds of pm to several meters. The longitudinal/thickness dimensions of such a sheet are from a pm to a few cm. The “plane of the sheet” hereunder refers to the two dimensional plane in the sheet that defines the lateral shape of the sheet.

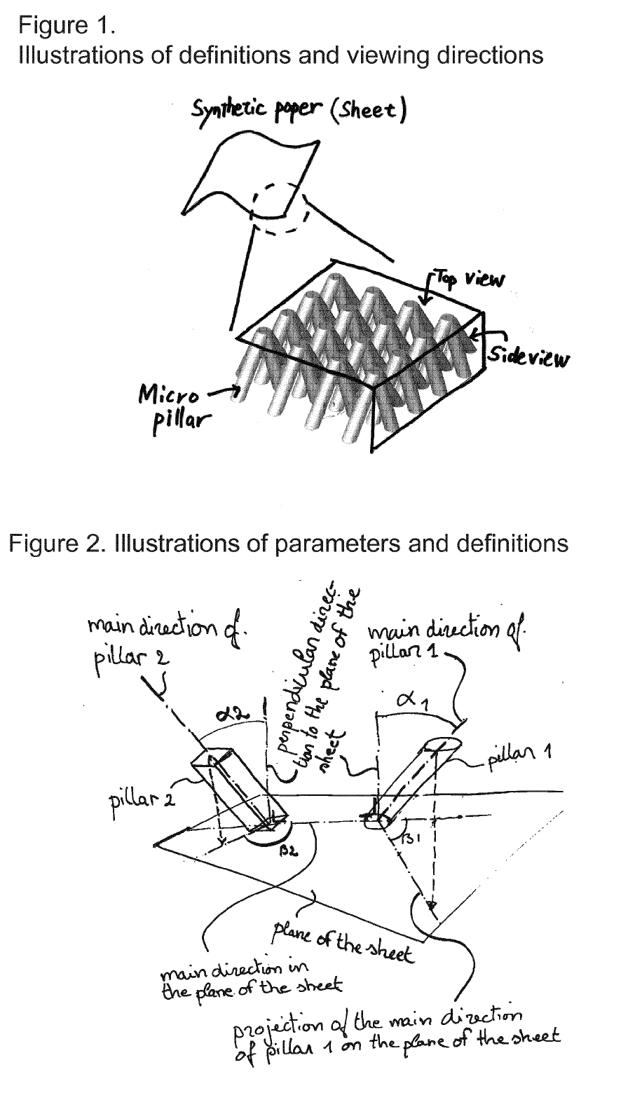

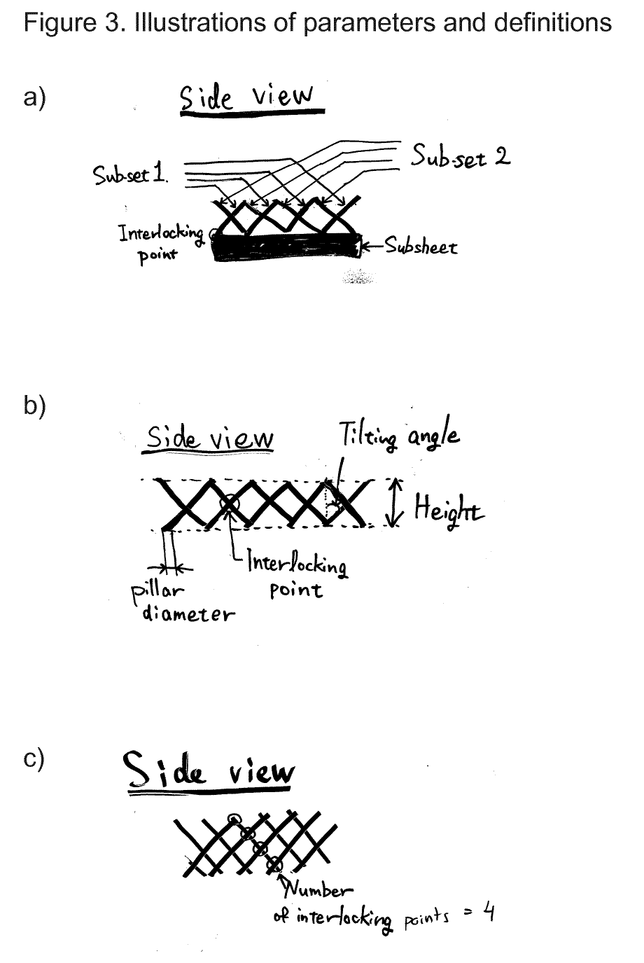

The word “micropillar” (referring to FIG. 1) hereunder refers to an elongated shaped microstructure with a length-to-cross-sectional size aspect ratio of larger than 1, with a main pillar axis along the length of the pillar and a cross-sectional shape perpendicular to the main pillar axis.

Each micropillar axis direction is defined by its tilting angle alfa and its tilting direction beta, in which alfa is defined as the angle between the pillar and the direction perpendicular to the plane of the sheet, and beta is defined as the angle between a main direction in the plane of the sheet and the direction of the perpendicular projection of the main pillar axis to the plane of the sheet (see FIG. 2). For micropillars that are perpendicular to the plane of the sheet, alfa is zero and the perpendicular projection of the main pillar axis to the plane of the sheet is a point, in which case beta is infinite.

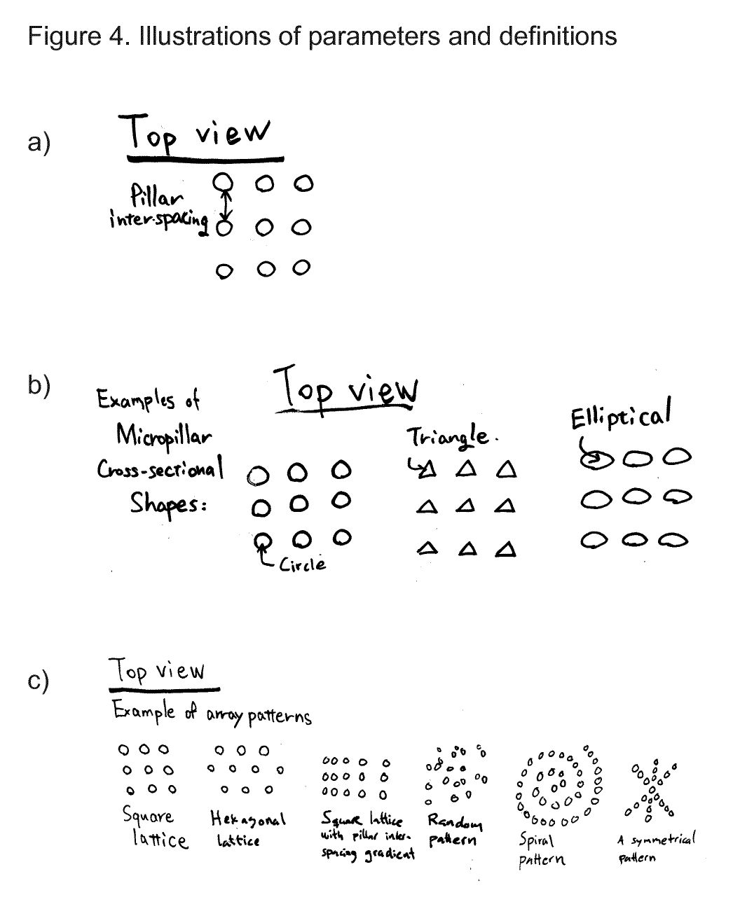

The cross-sectional shapes of the micropillars referred to hereunder can be arbitrarily chosen, with examples of cross-sectional shapes including circular, elliptical, rectangular, star shaped or other 2D geometries (see FIG. 4).

Micropillars feature a cross-sectional size that can be in the range between below 1 μm up to several hundred pm.

Micropillars feature lengths that can be in the range between below 1 μm up to a few cm.

The word “array” (see FIG. 4) hereunder refers to a group of pillars that could be placed either repetitive in a grid pattern, such as square lattice or a hexagonal lattice, a grid pattern with varying inter-pillar-distance, in a specific pattern, such as a spiral or a symmetric pattern, or in a completely random pattern with a certain density.

Exemplary embodiment 1 comprises: a sheet that comprises one or several arrays of micropillars, where the micropillars are arranged in the sheet and protruding from the plane of the sheet where at least two different subsets of micropillars feature main axis directions that are different (see FIG. 2).

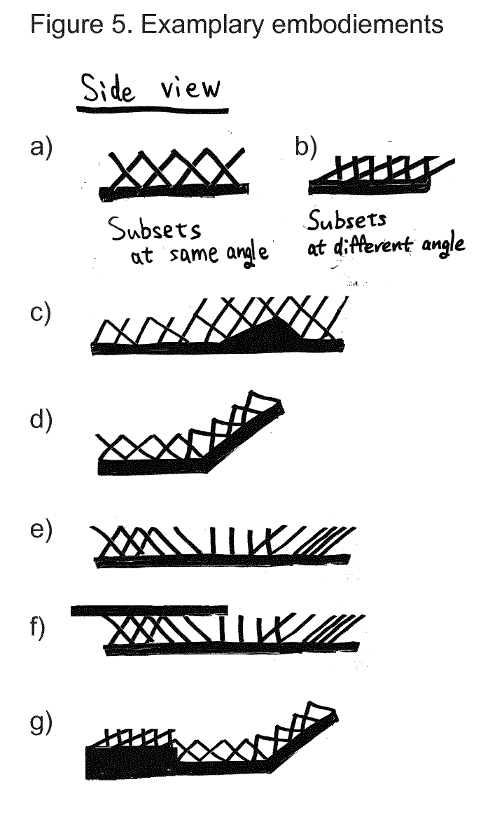

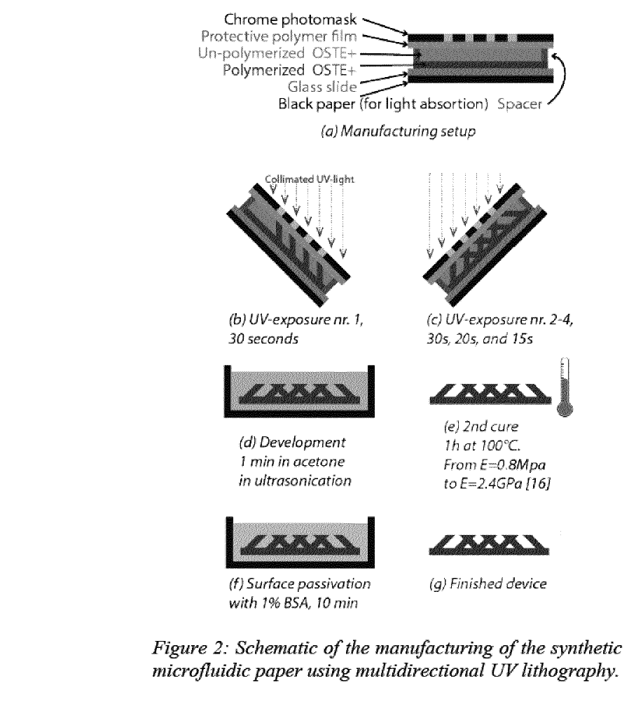

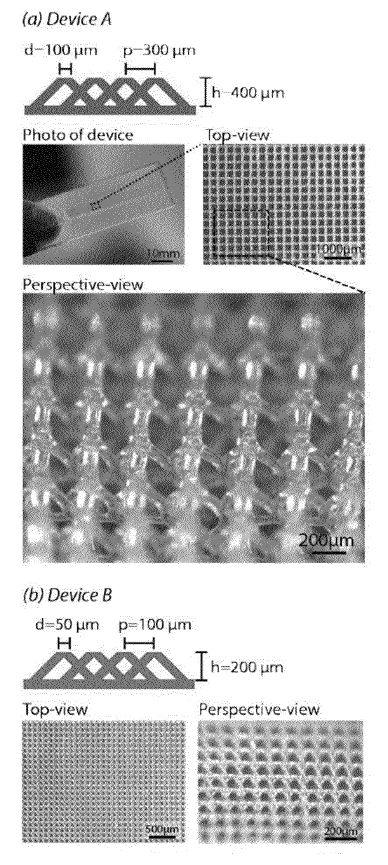

Exemplary embodiment 2 comprises a sheet comprising micropillars as in exemplary embodiment 1, in which at least two micropillars with different main axis direction are interlocked in at least one interlocking point (see e.g. FIG. 5e).

Exemplary embodiment 3 comprises a sheet comprising micropillars as in exemplary embodiment 1, in which every micropillar is interlocked with at least one other micropillar (see e.g. FIG. 5a).

The sheet may or may not contain subcomponents comprising one or several sheets of material, hereafter called subsheets (see FIGS. 5c, d, f, and g), which subsheets are in substantially the plane of the sheet, and to which subsheets micropillars are attached. In an exemplary embodiment, subsheet comprise a sheet of solid material only. Attachment of micropillars to the subsheet through connecting to a surface can be partial meaning some of the micropillars in an array may or may not be interlocked to a subsheet. Micropillars in an array can also be interlocked to different subsheets.

A sheet containing at least one subsheet may contain: micropillars that are only interlocked to a subsheet and not to other micropillars; micropillars that are interlocked to both a subsheet and to other micropillars, or; micropillars that are not interlocked to the subsheet but that are interlocked to other micropillars.

The microstructures comprise at least one material selected from the group consisting of thiol-enes, thiol-ene-epoxies. In one embodiment the micropillar material is chosen based on the Y-modulus so as to be able to get a sheet with adaptable mechanical, optical, or electromagnetic properties.

The material of the micropillars is thiol-enes, thiol-ene-epoxies or acrylates that can be photopolymerized.

The cross-sectional shape of the micropillars may be arbitrary including but not limited to circular, elliptical, rectangular and any other two-dimensional shape. In exemplary embodiments the micropillars are substantially circular cross-section.

The micropillars are in one embodiment arranged at a tilted angle in relation to a plane or surface of a sheet i.e. not being perpendicular to a plane or surface of a sheet. In one embodiment the tilting angle may be from 10° to 80° degrees. The tilting angles may vary between different micropillars or different sheets and/or arrays of micropillars or micropillars in different horizontal planes.

The micropillar height may vary from below 1 μm up to a few cm. Micropillars in an array or in a sheet can be of varying height. The aspect ratio (defined as height/diameter) for a micropillar may vary from 1 to several hundred.

The most important parameters that can be changed in this material are:
The sizes and geometry of the sheet itself
The material, including all material properties; Y-modulus etc.
Number of different arrays, and their geometrical relation to eachother
Shape of arrays
Number of subsheets and their geometrical relation to eachother
The geomerty of the pillars themselves
Pillar diameter
According to one embodiment, the cross-sectional diameter (or end-to-end distance) of the micropillars is 1-1000 μm.
Cross sectional shape
Tilting Angles (compared to vertical pillar)
Height
The array micropillar geometry may vary and what is Illustrated in the drawings represents only possible options. The micropillars can be arranged in regular or irregular formations/patterns. Moroever, the center-to-center distance between neighboring micropillars may be the same or may differ.
The inter-pillar geometries
Pillar interspacing, in terms of: (this will result in different “crystallography's”)
Distance
Pattern

A micropillar may have interlocking points with other micropillars. In one embodiment each micropillar has at least one interlocking point with another micropillar. An interlocking point is a point where two or more micropillars are joined together.
Number of interlock points per pillar (this will depend on other parameters such as pillar interspacing, height, and angle)
Tilting direction (angle compared to the tilting direction of other pillars)
Interlock point geometry, e.g. complete or partial interlock (this will depend on other parameters such as pillar interspacing pattern and angles). Partial interlock means that the cross sectional area of the pillar interlocking are only partially overlapping
Number of different tilting angles

### Synthetic Paper as Metamaterial

Metamaterials are artificial engineered materials that are assemblies of multiple individual elements fashioned from conventional materials such as metals or plastics, but the materials are usually constructed into repeating patterns, often with microscopic structures. Metamaterials derive their properties not from the compositional properties of the base materials, but from their exactingly-designed structures. Mechanical metamaterials are artificial structures with mechanical properties defined by their structure rather than their composition.

The present material is a mechanical metamaterial comprising sheet(s) with substantially repetitive pattern(s) of basic micropillar cells, which cells consist of one or several interlocked micropillars and some or all of their adjacent cavities. The basic micropillar cells thus form a repetitive pattern, which also allows describing the synthetic paper as a 2D or 3D macrocrystaline material, with specific crystal direction determined by the pattern in which the cells are repeated.

### Unique Features

In exemplary embodiments, the macroscopic behaviour of or the present synthetic paper can be designed by choosing the constituting pillar cross-sectional shape, inter-pillar angles, the amount, position and spatial distribution of the interlocking points, pillar density and interlocking point geometry.

In this way, for example the macroscale mechanical and/or fluidic and/or electromagnetic properties of the material can be designed to be of certain value, and the material can be designed to behave either isotropically or anisotropically with respect to those properties.

For example, in terms of strain-stress behaviour, a material/structure comprising the present synthetic paper/sheets whith micropillar structures can be designed to allow for a very large strain without plastic deformation or rupture. Whereas in traditional material sheets, the strain-stress characteristics are mainly determined by the material's Young's modulus, in the present synthetic paper it is in addition determined by the angle between pillars, which angle is changeable under stress. The macroscopic strain of the material is thus partly determined by the change in angle between the pillars when the sheet is stressed.

Other examples of mechanical behaviour obtainable by choosing the constituting pillar cross-sectional shape, inter-pillar angles, the amount, position and spatial distribution of the interlocking points, pillar density and interlocking point geometry are to get a controlled fracture process at certain mechanical loads, or deflect a strain to a desired direction.

In terms of fluidic properties, the fluidic resistance and the Laplace pressure drop over a liquid-air front in the synthetic paper can be both designed to have specific values in a specific direction in the synthetic paper by choosing the specific material surface contact angle, as well as the constituting pillar cross-sectional shape, inter-pillar angles, the amount, position and spatial distribution of the interlocking points, pillar density and interlocking point geometry.

In terms of electromagnetic properties, the effective electric permittivity and the magnetic susceptibility are determined by those of the materials that constitutes the pillars, as well as by what is in-between the pillars, the latter being nothing (vacuum), a gas, a liquid or a solid, or a combination thereof.

Moreover, the repetitively of the basic material cells can be designed to have a specific interference with electromagnetic waves of a wavelength that is matched with the interdistance of the cells that constitute the synthetic paper, such that its macroscopic properties result in an electromagnetic component, for example, but not limited to, a lens, a waveguide, a phase shifter or a mirror at those specific wavelengths. The electromagnetic components can be designed for electromagnetic waves of a certain range of frequencies, such as ultraviolet, visible light, infrared light, microwaves, or Terahertz waves.

Also, within the same sheet of synthetic paper one can include several regions with different basic pillar cell design, such that those regions each have their specific macroscale mechanical, fluidic and/or electromagnetic properties. The combination of different regions within one sheet can be designed to result in a specific mechanical or fluidic or electromagnetic function of the paper.

### Microfluidic Components Constituted by Synthetic Paper

To create microfluidic components such as channels, fluidic resistors, valves, reaction chambers and microfluidic mixers is traditionally done by, for example, molding or embossing structures in a thermoset or thermoplastic material or by printing hydrophobic materials, such as wax, in a hydrophobic paper sheet. In 2D micropillar forest devices consisting of vertical pillars, the components can be designed by the size, cross-sectional shape and pitch of the micropillars.

For example, pillars in 2D pillar forests can be spaced such that during filling with liquid, the air-liquid front follows a specific path, such as a meander shape, but the bulk liquid follows other pats, resulting in micromixer.

2D microfluidic channel structures can also be used to form passive capillary valves (Melin et al., lab chip, 2004), e.g. to stop a single the air-liquid front, from moving without either additional force added, or to that another air-liquid front arriving to a joint furcation.

However, 2D microfluidic pillar forests only allow 2D microfluidic networks.

### Unique Features

In exemplary embodiments, the 3D nature of the pillar placement in synthetic paper allows creating 3D microfluidic networks. Channels in such 3D network are formed by a set of interlocked interpillar spaces, hereafter referred to as the 3D channel, that are preferably filled by liquid, e.g. through capillary action, whereas the interpillar spaces immediately adjacent to the 3D channel are prevented from filling because the connections between the 3D channel and those adjacent spaces form a geometric capillary valve, i.e. surface energy prevents a phase interface, such as a liquid-air front, from passing through such connection without applying an additional pressure drop over the interface.

Alternatively, a 3D variant of the 2D micromixer design by Melin et al (lab chip, 2004) can be made, in which the geometric capillary valves between two sections of a 3D meandering channel works as a valve if one of the channel sections is filled with a hydrophilic liquid while the other section is filled with air or another hydrophobic fluid. However, when both channel sections both contain hydrophobic or both contain hydrophilic liquid, the valve is open and allows fluid flow through the valve. The benefit of a 3D microfluidic structure over a 2D microfluidic structure is that there can be a larger degree of chaotic advection in a 3D structure, resulting in a faster and more complete mixing process.

Synthetic paper can also be designed to automatically create a 2D or a 3D array of droplets when dipped into a liquid or when liquid is pressure forced through it. This can be accomplished by designing the interpillar voids such that some preferably fill with liquid, either by spontaneous capillary filling or under moderate pressurisation, whereas the voids between different liquid filling voids remain dry due to capillary valving action by the connections between those dry voids and the filled voids and the surrounding. Such droplet arrays can be designed to have very specifically designed droplet volumes such that the total set of droplets are designed for performing a digital bioassay such as digital ELISA or digital PCR.

The benefit of using synthetic paper as a platform for performing digital assays is the ease in which the droplet array can be created and the fact that such array can be 3D in nature, such that the area of the sheet required to create a certain total volume of liquid droplets is smaller than that of a 2D array, which requires a smaller area to be scanned during operation, compared to a 2D array of droplets, which allows for a faster or lower cost operation of the digital assay.

### In situ Hydrophilic and Hydrophobic Patterning

Hydrophilic and hydrophobic patterns are indispensable in many microfluidic applications since fluidic behavior is greatly influenced by the contact angle of a liquid and channel walls. For example, controlled hydrophilicity is important to ensure proper flow rates and hydrophobic regions sometimes serve as liquid flow stops at certain parts of a device since the liquid requires external forces to pass the barrier of the hydrophobic region. In other applications, spotting of bioreagents such as antibodies or antigens require careful matching of the surface tension of the liquid and the surface energy of the substrate to ensure good spot morphology.

Currently, both hydrophilic and hydrophobic regions are made via secondary surface functionalization steps, which adds cost and complexity to device fabrication.

### Unique Features

Exemplary embodiments utilize only one surface modification solution, consisting of one photolatent acid, a solvent, a molecule with at least one electron rich carbon carbon double bond (vinyl ether, allyle ther for example) and/or a molecule containing an epoxy, a radical inhibitor and a molecule with an electron poor carbon carbon double bond (an acrylate or a maleate for example). The liquid surface modification solution is dispensed to cover a substrate with unreacted thiol groups and a photomask is placed on top, either in contact or in proximity. UV-light of a proper wavelength is shone on the mask, which converts the photolatent acid into a strong acid which initiates cationic cure of the electron rich carbon carbon double bonds or the epoxy. The electron poor carbon carbon bond is unreactive via cationic cure and the released acid prevents Michael addition to the thiol. In the unexposed parts thiols are spontaneously reacted with the electron poor carbon carbon double bonds.

If a more rapid conversion rate is desired for the spontaneous reaction, a weak base, such as a tertiary amine, is added to the solution prior to exposure.

In another embodiment, a radical initiator is added to the solution. When exposed to a wavelength with sufficient energy to activate the radical initiator, but insufficient to activate the photolatent acid, reactions between the electron poor carbon carbon double bond and thiol will dominate and when a wavelength of sufficient energy to activate both types of reaction, a mixed reaction will take place, giving the surface a character of both types of monomers.

### Mechanical Particle Filter

Mechanical filtration is an operation used for the separation of solid particles from fluid by filters through which only the fluid can pass. As the filter, porous or reticulate substances, such as a filter paper, are often used and the size of removed particles is dependent on that of inner space of the pore or reticular. The applications of the mechanical filtration range widely from sewage treatment to microfiltration, which separates microorganisms from the liquid. As the size of target particle decreases, filters with well-defined inner space of pore or reticular are required for precise and reproducible filtration.

### Unique Features

In exemplary embodiments, the present synthetic paper has repetitive interlocked pillar patterns that can work as a mechanical filter. In spite of liquid propagation, removed particles can be mechanically trapped in the inner space surrounded by the interlocked pillars. The sizes and geometries of inner space is created by properly choosing the array pattern, cross-sectional shape, and inter-pillar distances, interval distance and tilting angle of pillars, and hence it is possible to perform filtration with an appropriate threshold on the size of the particles to suit its use. The present examples exhibited inter-pillar distances with ten and several micro meters and it is possible to fabricate several micron of interlocked structures, which allows microfiltration, such as blood filtration to remove cells from whole blood, resulting in, e.g., blood plasma.

Furthermore, by combining the filtration mechanism with a feature of the present synthetic paper as capillary pump, autonomous filtration of the sample liquid can be achieved. The capillary pump is a microfluidic component that drives liquid in a narrow channel by capillary force depending on surface energy and viscosity of the liquid. The repetitive structure of the present synthetic paper also represents a function as capillary pump under the condition of proper surface energy. The two inherent functions, the mechanical filter and capillary pump, work at the same time, i.e., an autonomous filtration system is obtained where a needed operation is only to fill the synthetic paper into the sample liquid. This simple system can be applied to a rapid diagnostic system based on lateral flow assay.

Additionally, since pillar density and cross-sectional shape and magnitude are locally designable, it is allowed for the present synthetic paper to obtain local functional structure, which feature is not achievable in random-structured filter like a normal paper filter. For example, implementing arrays of different sizes of inner space together, the affection against liquid propagation due to instant clogging of microorganisms can be avoided.

### Lateral Flow Assay

Lateral flow devices (LFD), e.g. the pregnancy dipstick test, are traditionally manufactured using nitrocellulose substrates. Nitrocellulose, and the more recently introduced microfluidic paper substrates consist of natural material based products and therefore suffer from batch-to-batch variations in structure, surface properties, and optical transparency. This natural variability and the low material transparency form a fundamental limit to the cut-off value (CV) that can be reached with such LFDs.

Micropillar arrays form a superior lateral flow substrate alternative providing higher sensitivity, lower CVs, and higher resolution in quantitative measurements, at least in part due to the reproducibility in geometry and surface chemical characteristics. Indeed, today's most sensitive commercial LFD is polymer micropillar-based. Polymer micropillars for lateral flow devices have been manufactured in COC (Cyclic Olefin Copolymer) with an aspect ratio (a.r.) of 1, in PMMA with a.r. 0.05, in PDMS with a.r. 0.12, and in SU-8 with a.r. 0.34. Downscaling and increasing the a.r. of pillars increases the reaction surface/volume but is limited by random pillar collapse due to capillary forces exerted between adjacent pillars during development or filling, The minimum required material stiffness required to avoid capillary collapse is

$${E}_{crit} = \frac{32 \sqrt{2} {γcos}^{2} θ \cdot {h}^{3} f ( r )}{3 {d}^{4}}$$

where d, h and p are pillar diameter, height and pitch, respectively, θ is the equilibrium contact angle, γ is the liquid-vapor interfacial energy, and ƒ(r) is a function of r=p/d. Using silicon as a very high stiffness substrate material addresses this issue. However, silicon LFDs are too costly for the majority of applications.

### Unique Features

In exemplary embodiments, to overcome the problem of low polymer material stiffness a multidirectional UV lithography is used that has been used to create 3D inclined structures in photoresists previously, and for lab-on-a-chip applications, mainly as an isoporous particle filter in SU-8.

We introduce a microfluidic substrate that comprise of a dense, high aspect ratio, stiff polymer micropillar array with thin slanted pillars that are mechanically interlocked.

The micropillar-interlocking configuration of the synthetic microfluidic paper introduced in this work results in a mechanical stability that allows miniaturization and increased aspect ratio of micropillars in capillary pumps beyond previously demonstrated vertical pillar geometries. The high aspect ratio pillars allow large surface area that can be functionalized with detector molecules. Using Off-Stoichiometry-Thiolene-Epoxy (OSTE+), or Off-Stoichiometry-Thiolenes, the large surface area is also observable through multiple layers of pillars and interlocks. The synthetic paper also has highly invariable geometry and surface properties, providing extremely low variability within and between batches. The repeatable structure with no dead ends (like nitrocellulose) makes pinning and other complex interactions with local geometries highly repeatable instead of random (as for cellulose based substrate), leading to better repeatability and better control of the fluid flow.

By choosing the constituting pillar cross-sectional shape, inter-pillar angles, the amount, position and spatial distribution of the interlocking points, pillar density and interlocking point geometry differently in different areas of the material, local regions can be design to be functionalized by spotting volumes functional molecules in liquid, with repeatable morphology of the spots, regardless of spotting inaccuracy within certain limits.

### Stretchable Electronics and Artificial Skin

Flexible substrates for surface mounted electronics is becoming increasingly popular due to demands on more efficient packaging of electronics in consumer products such as cameras and mobile phones and in emerging technologies such as artificial skin with tightly packed sensors. Through hole vias are challenging in flexible substrates since the plastics typically used are difficult to micromachine in an effective manner.

Flexible substrates are limited in stretchability due to breakage of electrical contact.

### Unique Features

In exemplary embodiments, the geometry obviates the need for micromachining of through holes since the substrate already is porous. This enables easy creation of through hole interconnects in flexible printed circuit boards.

For both flexible PCBs and flexible skin, the ability to utilize structures that are inherently flexible enables use of significantly stiffer polymers than those currently used. This increases the choices of polymer properties to enhance higher temperature performance, bonding to other substrates and to metals (where the material currently used for artificial skin, PDMS, is notoriously difficult to surface modify and bond to metals).

The synthetic paper allows easy coating with electrode materials, e.g. such as gold. Examples of such processes are chemical bonding of gold to thiol on the surface of an OSTE/OSTE+ polymer.

An interesting feature of the resulting material is the ability for large stretching without breaking the electrical galvanic contact in the electrical connection lines. This follows from the macroscopic strain of the synthetic paper resulting partially from the local rotational strain of the pillars at their joints, rather than by mere elongation of the pillars themselves.

### Micro Origami With Self-Assembly of Synthetic Paper

Self-assembly is an autonomous phenomenon to construct significant structure without intervention, appearing in the various phenomena existing in nature such as DNA duplex formation and snowflake crystal. In engineering, the self-assembly has been recently recognized as a key tool to construct complicated three-dimensional structure in micro and nanometre scale, which is sometimes described as “Origami” [1]. To give rise to the self-assembly in an engineered structure, it is required to properly controlling a self-actuation mechanism by external or inherent propulsion.

There is a wide range of methods to bring about self-actuation in an engineered structure but to combine two layers with different property for each is one of the simplest methods to achieve it. For example, when the two layers have different property of shrinkage against a certain stimulation (heat, light exposure, etc.), the combined layers are bent such that the layer with greater shrinkage is on the convex side.

### Unique Features

In exemplary embodiments, thanks to two-step photolithographic ability, it is possible to combine several layers of the present synthetic paper with defined different property (e.g. stiffness, elasticity, shrinkage against heat, and surface energy) on the process of the fabrication.

Repetitive interlocked pillar patterns in the present synthetic paper effectively work for the mentioned self-actuation mechanism since the properties are controllable by tuning the cross-sectional shape and magnitude, interval distance and tilting angle of pillars and drastically changed compared with normal sheet material. In addition with the actuation mechanism by shrinkage difference, difference between layers in terms of hydrophilicity possibly works for the actuation; hydrophilic interlocked pillars are patterned on hydrophobic paper sheet. When sufficient amount of water drop to fill several hydrophilic patterns is injected on the hydrophilic pillar side, the hydrophilic patterns sequentially surround the drop and then the whole paper is bent.

These actuations allow self-assembly of the present synthetic paper and depending on prepared shape of the paper, 3D geometric shapes, e.g. a cube, can be achieved. Utilizing the actuation and the forms, micro gripper to trap cell or microorganisms has been invented [2], and they should be potentially possible to achieve with the present synthetic paper. Unlike the conventional material, the present synthetic paper has open interface via inner space supported by the interlocked pillars that connect the internal space of the form and external environment. This feature will be useful for trapping biological components such as cells or microorganisms, which require continual communication with external environment for oxygen acquisition.

Furthermore, the material can be designed to have very specific mechanical behavior, e.g. to get a controlled fracture process and pattern under certain strain, or deflect a strain to a certain direction.

### Synthetic Three-Dimensional Textile by Interlocked Fiber

Over the long human history textile has been playing an important role in our life. The use of textile material is nowadays expanded in advanced technology from aerospace application to advanced blood vessels. The textile material basically comprise two-dimensional network of woven thread. However three-dimensional woven structures has been also studied because the 3D textile leads to applications in various engineering fields of aircraft, marine vessels, civil infrastructure and medical prosthesis.

### Unique Features

In exemplary embodiments, the inner structure of the present synthetic paper can be recognized as textile with uniqueness of interlocked polymer fiber. The unique inner feature will bestow excellent functionalities on the synthetic textile.

Firstly, the thickness of the present synthetic textile is simply enlarged owing to the support of the interlocking. It implies the 3D textile with the arbitrary thickness can be achieved. 3D textile is laborious to weave from conventional thread material with exclusive weaving machine but in the present synthetic textile it is theoretically possible to obtain a certain thickness of 3D textile at will. Taking the present fabrication process into account, the present synthetic textile is extraordinary simple in comparison with the conventional 3D-textile.

Next, focusing on the inner space surrounded by interlocked pillars, it is realized that there exist 3D array of defined spaces. The geometric parameters of the array effects macroscopic mechanical properties such as Young's module, shear modulus and thermal conductivity. Since the inner space can be tunable by changing the cross-sectional shape and magnitude, interval distance and tilting angle of pillars to suit its use, these mechanical properties are expected to be controllable, which promotes the use of the synthetic textile.

### Writing Paper

Various types of traditional cellulose based paper utilizes the capillary filling of paper in applications such as writing, printing and absorption of fluid.

### Unique Features

In exemplary embodiments, the present synthetic paper can also be used as such, with advantages in different applications:

Better adhesion of dye/ink for writing or printing. When certain monomer compositions (such as Off-Stoichiometric-Thiol-Enes) are used it could even be covalently bound to the substrate.

Optimized drying time, by choosing the constituting pillar cross-sectional shape, inter-pillar angles, the amount, position and spatial distribution of the interlocking points, pillar density and interlocking point geometry.

More even colour distribution or pixelated effect for writing or printing, depending on position and spatial distribution of the interlocking points, pillar density and interlocking point geometry.

When absorbing various fluids the structures and surface can be optimized to e.g. have a very steady filling speed of very high filling speed.

In some applications such as cleanroom use, papers for writing, printing and adoption should have a low tendency to loose particles (small pieces of fibre) when used, handled or mechanically cut into smaller pieces. The fact that all particles are mechanically interinterlocked can result in very few particle/fibre loss.

### Manufacturing of Synthetic Paper

The synthetic paper is manufactured by multidirectional photolithographic patterning.

The below paragraphs describe exemplary embodiments.

The multidirectional pholithographic patterning can be performed in one or multiple exposures, either one direction for every exposure (using only one light source) or multiple directions simultaneously (by using either multiple light sources and/or mirrors to direct light in multiple directions). Thus it is possible to make an entire complex pattern in one exposure by exposing from several angles simultaneously.

Off-Stoichiometry-Thiolene-Epoxy (OSTE+) and Off-Stoichiometry-Thiolenes, both with successful results. The off-stochiometry feature give an edge effect during the manufacturing process which allows for thinner micropillars and a sharper more well defined boundary.

In a typical formulation, a mixture of acrylate monomers (reactive diluents) and oligomers, a photoinitiator and a radical inhibitor is used. The initiator is chosen to be activated by actinic radiation and a photomask is used to define regions where solid structures are formed by actinic radiation initiated polymerization. The roles of the inhibitor are to extend shelf life of the mixture and to enhance pattern fidelity by suppressing pattern broadening via radical diffusion out from the illuminated zone.

The manufacturing method comprises reacting a compound comprising at least two thiol groups and a compound comprising at least two carbon-carbon double bonds, with the proviso that the ratio (r1) in the reaction mixture between the number of thiol groups and the number of carbon-carbon double bonds fulfils one of: 0.5≦r1≦0.9 and 1.1≦r1≦2, with photo polymerization to obtain the micro structure.

In one embodiment at least one of unreacted thiol groups and carbon-carbon double bonds on said microstructure are reacted with further reactive groups to modify the properties of said final article.

In one embodiment the reaction is performed in a distinct pattern.

In one embodiment the compound comprising at least one thiol group is selected from the group consisting of pentaerythritol tetrakis (2-mercaptoacetate), pentaerythritol tetramercaptopropionate (PETMP); 1-Octanethiol; Butyl 3-mercaptopropionate; 2,4,6-trioxo-1,3,5-triazina-triy (triethyl-tris (3-mercapto propionate); 1,6-Hexanedithiol; 2,5-dimercaptomethyl-1,4-dithiane, pentaerythritol tetramercaptoacetate, trimethylolpropane trimercaptoacetate, 2,3-dimercapto-1-propanol, 2-mercaptoethylsulfide, 2,3-(dimercaptoethylthio)-1-mercaptopropane, 1,2,3-trimercaptopropane, toluenedithiol, xylylenedithiol, 1,8-octanedithiol, 1-hexanethiol and trimethylolpropane tris(3-mercaptopropionate), and glycol dimercaptopropionate and pentaerythritol tetramercaptopropionate (PETMP).

In one embodiment the compound comprising at least one carbon-carbon double bond is selected from the group consisting of triallyl-1,3,5-triazine-2,4,6(1H,3H,5H)-trione; Triethyleneglycol divinyl ether (TEGDVE); Trimethylolpropane diallyl ether; Dodecyl vinyl ether (DDVE); 1,6-heptadiyne; 1,7-octadiyne; bis-2,2-[4-(2-[norborn-2-ene-5-carboxylate]ethoxy)phenyl]propane (BPAEDN); 1,6-hexanediol di-(endo,exo-norborn-2-ene-5-carboxylate) (HDDN); trimethylolpropane tri-(norborn-2-ene-5-carboxylate) (TMPTN); pentaerythritoltri-(norborn-2-ene-5-carboxylate) (PTN3); pentaerythritol tetra-(norborn-2-ene-5-carboxylate) (PTN4); tricyclodecane dimethanol di-(endo, exo-norborn-2-ene-5-carboxylate) (TCDMDN); and di(trimethylolpropane) tetra-(norbom-2-ene-5-carboxylate) (DTMPTN). In one specific aspect, the ene monomer is Triallyl-1,3,5-triazine-2,4,6-trione (TATATO). In another specific aspect, the ene monomer is trimethylolpropane tri-(norborn-2-ene-5-carboxylate) (TMPTN).

In one embodiment the microstructure comprises at least one epoxide.

In one embodiment the polyether is selected from the group consisting of Tris(2,3-epoxypropyl) isocyanurate, Trimethylolpropane triglycidyl ether, Tris(4-hydroxyphenyl)methane triglycidyl ether, Poly(ethylene glycol) diglycidyl ether, Bisphenol A diglycidyl ether 1,2,5,6-Diepoxycyclooctane, 1,2,7,8-Diepoxyoctane, 1,2-Epoxy-5-hexene, 1,4-Cyclohexanedimethanol diglycidyl ether, 3,4-Epoxycyclohexylmethyl 3,4-epoxycyclohexanecarboxylate, 4,4′-Methylenebis(N,N-diglycidylaniline), Bis[4-(glycidyloxy)phenyl]methane, Bis[4-(glycidyloxy)phenyl]methane, Diglycidyl 1,2-cyclohexanedicarboxylate, N,N-Diglycidyl-4-glycidyloxyaniline, Neopentyl glycol diglycidyl ether, Resorcinol diglycidyl ether, Tris(4-hydroxyphenyl)methane triglycidyl ether.

The OSTE polymers expose a high density of surface groups of thiol and epoxy, homogenously distributed over the surface. The density of surface groups can be controlled by the amount of off-stoichiometry. These surface groups can be utilized for covalent bond formation to other surfaces or free molecules. After the curing process, the material has no leachable monomers and compared with OSTE without epoxy, higher glass transition temperatures and E-moduli are achievable. If the OSTE comprises polyethers, the curing creates a soft polymer that can be sealed to the substrate. A subsequent second curing process hardens the polymer and increases Tg as it consumes all or some of the remaining thiol and polyethers. The polyether groups exposed on the surface also have an “epoxy gluing” effect to most materials, e.g. metals and plastics. The second curing is in one embodiment a thermal curing at 70° C. during 2 hours, in another embodiment the second thermal curing is carried out at 110° C. during 1 hour. In one embodiment a thermal second cure is carried out at 60-150° C. during 0.5-3 hours.

The reactions are initiated by actinic radiation, this is suitably carried out by using a photoactive initiator. In one embodiment the radiation is used during 3-100 seconds. In one embodiment the effect is 6mW/cm². In one embodiment the wavelength is 365 nm.

The room temperature mechanical properties of OSTEs are tailored by adjusting the stoichiometric ratios of the monomers (and/or the monomer functionality). The OSTE polymers expose a high density of surface groups of either thiol or ene, homogenously distributed over the surface. The density of surface groups is controlled by the amount of off-stoichiometry. These surface groups can be utilized for covalent bond formation to other surfaces or free molecules.

In a first aspect there is provided a method for forming a three-dimensional ordered open microstructure with micro pillars, the method comprising the steps of:
a) providing a volume comprising at least two types of monomers with the ability to undergo a polymerization reaction upon exposure to actinic radiation,
b) exposing the volume comprising at least two types of monomers to at least one three-dimensional light pattern creating a pattern in the volume comprising at least two types of monomers, and wherein the exposure energy of the light pattern is sufficient to induce a polymerization reaction to create a cured polymer in a pattern, and
c) removing uncured monomer to leave behind the three-dimensional ordered open microstructure, corresponding to the pattern,
wherein the volume comprises at least one monomer comprising at least two thiol groups and at least one monomer comprising at least two carbon-carbon double bonds, with the proviso that the ratio (r₁) in the reaction mixture between the number of thiol groups and the number of carbon-carbon double bonds fulfils one of: 0.5≦r1≦0.9 and 1.1≦r1≦2.

In one embodiment the volume comprises at least one monomer comprising at least one epoxy group.

In one embodiment the micro pillars have a largest cross sectional distance of from 1 pm to 1000 μm. For a non-circular cross section the largest cross sectional distance is the largest possible distance between two points at the circumference of the cross section. For a circular cross section it is the diameter.

In one embodiment the micro pillars have a cross sectional shape selected from the group consisting of circular, elliptical, rectangular, and star-shaped.

In one embodiment the micro pillars have a length in the interval from 1 μm to 3 cm.

In one embodiment the micro pillars have a length to cross sectional size aspect ratio of larger than 1.

In one embodiment at least a fraction of the micro pillars are interlocked with at least one neighboring micro pillar in at least one interlocking point.

In one embodiment two micro pillars interlocked to each other have different main axis directions.

In one embodiment the open microstructure has a thickness in the interval from 1 μm to 3 cm.

In one embodiment the open microstructure has a maximum lateral dimension in the interval 200 μm to 3 m.

In one embodiment at least a fraction of the micropillars are interlocked to at least one subsheet.

In one embodiment every micro pillar is interlocked with at least one other micro pillar.

In one embodiment the micro pillars are arranged in at least one pattern selected from the group consisting of a square lattice, a hexagonal lattice, a grid pattern with varying inter-pillar-distance, a spiral pattern, a symmetric pattern, and a random pattern.

In one embodiment the tilting angle between the micro pillars and the direction perpendicular to the microstructure is in the interval 10°-80°.

In a second aspect there is provided a microstructure comprising micro pillars manufactured with the method described above.

In one embodiment the surface of the microstructure is at least partially surface modified. In one embodiment this is made by a chemical reaction with unreacted thiol or ene groups on the surface. With the off stoichiometry feature at least some groups will remain unreacted and these unreacted groups may serve as a reaction spot where other chemical groups can be attached by subsequent reactions. Thus it is possible to attach a huge variety of desired chemical groups and/or molecules on the surface.

In a third aspect there is provided the use of the microstructure manufactured according to the method described above for at least one selected from the group consisting of a microfluidic component, a mechanical particle filter, a lateral flow assay device, a stretchable electronic device, artificial skin, self-assembling systems, a synthetic textile, and a writing paper.

All the described alternative embodiments above or parts of an embodiment can be freely combined without departing from the inventive idea as long as the combination is not contradictory.

Other features and uses of the invention and their associated advantages will be evident to a person skilled in the art upon reading the description and the examples.

It is to be understood that this invention is not limited to the particular embodiments shown here. The embodiments are provided for illustrative purposes and are not intended to limit the scope of the invention since the scope of the present invention is limited only by the appended claims and equivalents thereof.

### EXAMPLES

The synthetic microfluidic paper is manufactured in an Off-Stoichiometry-Thiolene-Epoxy (OSTE+) polymer (OSTEMER Crystal Clear, Mercene Labs, Sweden). Photolithographic definition of the slanted pillars is performed using a collimated, near-UV mercury lamp (OAI, Milpitas) (12 mW/cm2 @ 365 nm) and the development process is done in acetone (VWR, USA) under ultrasonication (Model B220).

### Fabrication of Synthetic Microfluidic Paper is Done in Several Steps

(FIG. 2). First, a flat solid OSTE+ layer is manufactured by casting a 1000 pm thick layer of OSTE+ prepolymer between a 100 μm thick transparency film (Nordic Office, Sweden) and a glass slide (VWR, USA), followed by illuminating the prepolymer for 60 s. On top of the polymerized OSTE+flat layer, first 400 pm (Device A) or 200 μm (Device B) spacers are placed, then OSTE+ prepolymer is added, after which the polymer is squeezed by a top lid consisting of a glass-chrome photomask (JD Photo-Tools, UK) that is protected by a polymer film (“Never Tear 53my Clear Cling”, Antalis AB, Sweden). The entire stack is placed on a black paper (to avoid light reflection) and tilted ˜45° under 30 s or 20 s of UV-exposure, for Device A and B, respectively. Subsequently, the stack is tilted ˜45° in the opposite direction and illuminated using the same UV exposure conditions. In the directions perpendicular to the first two tiltings, exposure was performed with ˜30° tilting for 20 s and 15 s, and for 15 s and 10 s, for Device A and B, respectively. The 4 exposures are followed by development in acetone for 5 min under ultrasonication, and a second thermal cure for 1 h at 110° C. Finally, the surface of the substrate is passivated by incubating the substrates in 1% w/w BSA solution for 10 min and subsequent drying at room temperature.

The interlocked pillar geometry is defined by the photomask pattern consisting of transparent circles with diameter (d) 100 μm and pitch (p) 300 μm (for Device A) or d=50 μm and p=100 μm (for Device B). The pillar arrays are fabricated as strips of 5 mm width and 50 mm length.

For comparison, two devices were manufactured with vertical pillar arrays, using vertical UV-exposure, as “negative controls” using the masks with array geometries d=100 μm, p=300 μm (same mask as Device A) and d=100, p=200 μm (similar effective pillar density as Device A).

To evaluate the transparency of the slanted pillars, a human hair was inserted between the interlocked pillars along the bottom substrate of Device A, and imaged using bright field microscopy (Leica M205C with Leica DFC290 camera).

The capillary filling properties of the synthetic microfluidic paper was tested by pipetting DI-water colored with red dye, or human whole blood at one end of the 5 mm×50 mm slanted pillar array strips. The filling was filmed with a digital camera (Canon EOS 600D, with Canon Macro Lens EF 100 mm 1:2,8 USM) and still images at 7 time points (from t=0 s to t=150 s) were captured, cropped around the pillar strip and separated into different color channels. The filled area at each time point was calculated by subtracting the green channel value from the red channel value and classifying every pixel with an intensity >0 as filled. This method proved to provide accurate area measurement results. The volume per filled area was calculated by applying a known volume in the middle of an identical device, imaging the device after capillary filling was completed, and calculating the area with the method described above.

Finally, the synthetic microfluidic paper was tested as traditional paper by writing on it with a ball point pen (Pilot G2 07, red color). The word “Hello” was written on the slanted pillars (i.e. on the synthetic microfluidic paper), and the word “World” was written on the adjacent flat polymer substrate. Soon after writing a finger is swiped along both words to test the robustness of the writing on both types of surfaces.

Device A and Device B (d=50 μm, h=200 μm, p=100 μm) were both successfully manufactured with repeating units of slanted interlocked pillars (FIG. 7).

The “negative control” devices with freestanding vertical pillars of similar geometry as Device A featured capillary pillar collapse during development in acetone. This is due to the E-modulus during acetone development E_{dev}≈1 MPa [16]<<E_{crit}˜2 GPa.

Hence, the micropillar-interlocking configuration of the synthetic microfluidic paper introduced in this work results in a mechanical stability that allows miniaturization and increased aspect ratio of micropillars in capillary pumps beyond previously demonstrated vertical pillar geometries.

The human hair is very well visible through the slanted pillars, illustrating the good optical transparency of the devices. Unlike opaque materials such as nitrocellulose or paper, our synthetic paper transparency allows the simultaneous observation of several surface layers at several vertical positions. In a LFD, the observation of reaction product on a multitude of vertically lined surface layers potentially enables measuring lower concentrations.

We successfully performed capillary pumping of whole blood at 2.4 μl/min in device A and pumping of aqueous food dye at 15 μl/min and 0.38 μl/min in devices A and B, respectively.

Finally, we successfully tested our synthetic microfluidic paper as a traditional paper by writing on it with a ball-pen; without the pillars the ink easily smudges; with pillars it stays

1. A method for forming a three-dimensional ordered open microstructure with micro pillars, the method comprising the steps of:
a) providing a volume comprising at least two types of monomers with the ability to undergo a polymerization reaction upon exposure to actinic radiation,
b) exposing the volume comprising at least two types of monomers to at least one three-dimensional light pattern creating a pattern in the volume comprising at least two types of monomers, and wherein the exposure energy of the light pattern is sufficient to induce a polymerization reaction to create a cured polymer in the pattern, and
c) removing uncured monomer to leave behind the three-dimensional ordered open microstructure, corresponding to the pattern,
wherein the volume comprises at least one monomer comprising at least two thiol groups and at least one monomer comprising at least two carbon-carbon double bonds, with the proviso that the ratio (r1) in the reaction mixture between the number of thiol groups and the number of carbon-carbon double bonds fulfils one of: 0.5≦r1≦0.9 and 1.1≦r1≦2.

2. The method according to claim 1, wherein the volume comprises at least one monomer comprising at least one epoxy group.

3. The method according to claim 1, wherein the micro pillars have a largest cross sectional distance of from 1 μm to 1000 μm.

4. The method according to claim 1, wherein the micro pillars have a cross sectional shape selected from the group consisting of circular, elliptical, rectangular, and star-shaped.

5. The method according to claim 1, wherein the micro pillars have a length in the interval from 1 μm to 3 cm.

6. The method according to claim 1, wherein the micro pillars have a length to cross sectional size aspect ratio of larger than 1.

7. The method according to claim 1, wherein at least a fraction of the micro pillars are interlocked with at least one neighbouring micro pillar in at least one interlocking point.

8. The method according to claim 1, wherein two micro pillars interlocked to each other have different main axis directions.

9. The method according to claim 1, wherein the open microstructure has a thickness in the interval from 1 μm to 3 cm.

10. The method according to claim 1, wherein the open microstructure has a maximum lateral dimension in the interval 200 μm to 3 m.

11. The method according to claim 1, wherein at least a fraction of the micropillars are interlocked to at least one subsheet.

12. The method according to claim 1, wherein every micro pillar is interlocked with at least one other micro pillar.

13. The method according to claim 1, wherein the micro pillars are arranged in at least one pattern selected from the group consisting of a square lattice, a hexagonal lattice, a grid pattern with varying inter-pillar-distance, a spiral pattern, a symmetric pattern, and a random pattern.

14. The method according to claim 1, wherein the tilting angle between the micro pillars and the direction perpendicular to the microstructure is in the interval 10°-80°.

15. The method according to claim 1, wherein the microstructure is subjected to a second thermal cure.

16. A microstructure comprising micro pillars manufactured with the method according to claim 1.

17. The microstructure according to claim 16, wherein the volume comprises at least one monomer comprising at least one epoxy group.

18. The microstructure according to claim 16, wherein the micro pillars have a largest cross sectional distance of from 1 μm to 1000 μm.

19. The microstructure according to claim 16, wherein the micro pillars have a cross sectional shape selected from the group consisting of circular, elliptical, rectangular, and star-shaped.

20. The microstructure according to claim 16, wherein the micro pillars have a length in the interval from 1 μm to 3 cm.

21. The microstructure according to claim 16, wherein the micro pillars have a length to cross sectional size aspect ratio of larger than 1.

22. The microstructure according to claim 16, wherein at least a fraction of the micro pillars are interlocked with at least one neighbouring micro pillar in at least one interlocking point.

23. The microstructure according to claim 16, wherein two micro pillars interlocked to each other have different main axis directions.

24. The microstructure according to claim 16, wherein the open microstructure has a thickness in the interval from 1 m to 3 cm.

25. The microstructure according to claim 16, wherein the open microstructure has a maximum lateral dimension in the interval 200 μm to 3 m.

26. The microstructure according to claim 16, wherein at least a fraction of the micropillars are interlocked to at least one subsheet.

27. The microstructure according to claim 16, wherein every micro pillar is interlocked with at least one other micro pillar.

28. The microstructure according to claim 16, wherein the micro pillars are arranged in at least one pattern selected from the group consisting of a square lattice, a hexagonal lattice, a grid pattern with varying inter-pillar-distance, a spiral pattern, a symmetric pattern, and a random pattern.

29. The microstructure according to claim 16, wherein the tilting angle between the micro pillars and the direction perpendicular to the microstructure is in the interval 10°-80°.

30. The microstructure according to claim 16, wherein the surface of the microstructure is at least partially surface modified.

31. A device comprising a microstructure manufactured according to claim 1, wherein the device is selected from the group consisting of a microfluidic component, a mechanical particle filter, a lateral flow assay device, a stretchable electronic device, artificial skin, self-assembling system, a synthetic textile, and a writing paper.
